(19) United States
(12) Patent Application Publication
(10) Pub. No.: US 2003/0154922 A1
(43) Pub. Date: Aug. 21, 2003

(54) C-chuck insulator strip

(76) Inventor: Nathan House, Kuna, ID (US)

Correspondence Address: JOSEPH W. HOLLAND, HOLLAND & THIEL, P.C., PO BOX 1840, BOISE, ID, 83701-1840, US

(21) Appl. No.: 10/365,950

(22) Filed: Feb. 11, 2003

Related U.S. Application Data
(60) Provisional application No. 60/358,487, filed on Feb. 19, 2002.

(51) Int. Cl. C23C 16/00; C23F 1/00; H01L 21/306

(52) U.S. Cl. 118/725; 118/728; 118/729; 118/500; 118/723 E; 156/345.52; 156/345.43

(57) ABSTRACT

A susceptor assembly and an insulator strip for a susceptor assembly to reduce or eliminate arcing and temperature spikes between a ground cable and a thermocouple wire in susceptor and C-chuck assemblies. In one embodiment of the invention, an insulator strip is placed between the thermocouple lead and the ground cable in a susceptor assembly support arm channel.

### BACKGROUND OF THE INVENTION

1. Technical Field

This invention relates generally to the field of susceptor assemblies as generally used to process semiconductor substrates and more particularly to an insulator for placement between a ground conductor and a thermocouple lead.

2. Background Art

Susceptor and C-chuck assemblies are commonly used in processing chambers to support a wafer opposite a gas distribution plate. U.S. Pat. No. 5,522,937 to Chew, et al. entitled Welded Susceptor Assembly, which is incorporated by reference herein, discloses a susceptor assembly for use in a substrate processing chamber. The susceptor assembly includes a ceramic susceptor support arm having a channel formed along an underside of the support arm and an opening in the susceptor end of the ceramic susceptor support arm. A ground connection passes through the channel between the susceptor and a ground. The ground conductor is typically configured as a wire rope or cable, preferably made of aluminum, which is conductively connected at a first end to the susceptor disk and at a second end to a system ground. Similarly, a thermocouple lead passes through the channel to a thermocouple. A set of grooves in the bottom sides of the channel slidably receive a channel cover to isolate the ground wire and a thermocouple lead from the processing chamber environment.

Failure of susceptor and C-chuck assemblies has in some instances been traced to two causes, thermocouple failures due to arcing from the ground cable to a nickel sheath surrounding the thermocouple wires, or internal thermocouple faults relating to junction or grounding problems. The result of a failure is premature removal and replacement of the C-chuck assembly during operation or failure-on-install.

There may be advantage found in developing an apparatus and/or method for isolating or insulating the ground cable and thermocouple lead as they pass through the support arm of a susceptor assembly.

### SUMMARY OF THE INVENTION

The present invention is directed to an insulator strip for a susceptor assembly to reduce or eliminate arcing and temperature spikes between the ground cable and the thermocouple wire in susceptor and C-chuck assemblies. In one embodiment of the invention, an insulator strip is placed between the thermocouple lead and the ground cable in a susceptor assembly support arm channel. The insulator strip may be shaped to conform to the geometry of the channel in the support arm. Preferably, the insulator strip is made to fit within the channel of the support arm somewhat loosely in order to facilitate installation and to reduce the chances of breakage in installation and operation. The insulator strip should be adequately held in place by the ground cable, support arm cover, and surrounding components.

The insulator strip is preferably constructed of 99.5% aluminum oxide, or the same material as support arm. The insulator strip may be configured having a bend at one end to facilitate the bend of the thermocouple from the arm down to the platter as well as a backside locking member to hold the insulator strip in place and provide limited protection of the thermocouple as it is routed from the support arm to a housing body.

It will be noted that the support arm channel may have to be enlarged to accommodate the addition of the insulator strip between the ground cable and the thermocouple. The support arm of existing susceptor and C-chuck assemblies may be modified to include a shallow groove running along the inside bottom of the support arm to accommodate the added combined thicknesses of the thermocouple, the insulator strip and the ground cable. The groove may also serve to keep the thermocouple sheath centered in the arm and to minimize the possibility of crushing damage to the insulative sheath of the thermocouple.

The present invention consists of the device and system hereinafter more fully described, illustrated in the accompanying drawings and more particularly pointed out in the appended claims, it being understood that changes may be made in the form, size, proportions and minor details of construction without departing from the spirit or sacrificing any of the advantages of the invention.

### BRIEF DESCRIPTION OF THE DRAWINGS

FIG. 1 is a representative cross-section of a processing chamber including a susceptor assembly;

FIG. 2 Is a representative blow-up view of a susceptor support arm, thermocouple lead, grounding conductor, channel cover and an insulator strip according to the present invention;

FIG. 3 is a representative top view of a susceptor support arm according to the present invention;

FIG. 4 is a representative side view of a susceptor support arm according to the present invention;

FIG. 5 is a representative bottom view of a susceptor support arm according to the present invention;

FIG. 6 is a representative cross-section of a susceptor support arm according to the present invention;

FIG. 7 is a representative top view of an insulator strip according to the present invention;

FIG. 8 is a representative side view of an insulator strip according to the present invention;

FIG. 9 is a representative side view of an insulator strip according to the present invention;

FIG. 10 is a representative side view of an insulator strip according to the present invention;

FIG. 11 is a representative cross-section of an insulator strip according to the present invention;

FIG. 12 is a representative side view of an insulator strip according to the present invention; and

FIG. 13 is a representative cross-section of an insulator strip according to the present invention.

### DESCRIPTION OF THE PREFERRED EMBODIMENT

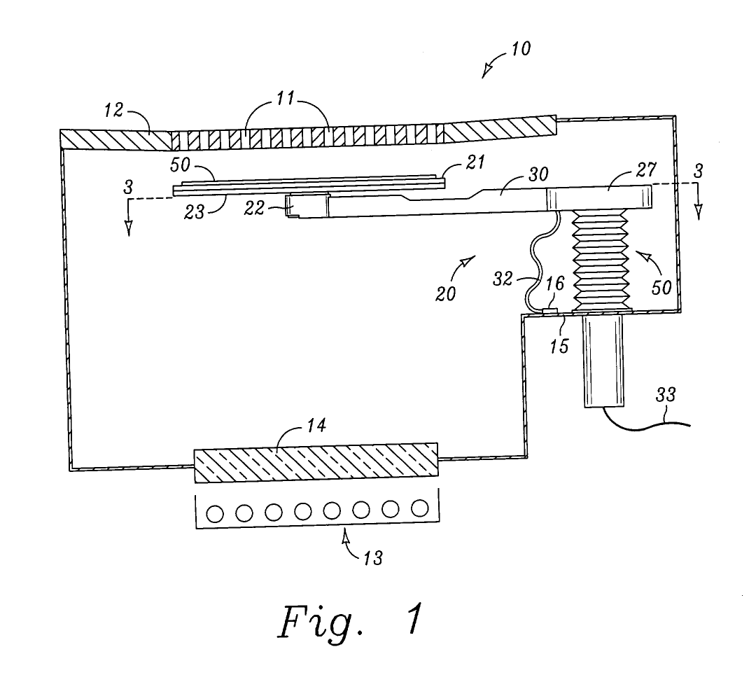

Referring to in FIG. 1, a typical configuration of a vapor deposition processing chamber 10 is shown including susceptor assembly 20 according to one embodiment of the invention. Susceptor assembly 20 is shown including susceptor plate 21. Susceptor plate 21 is backed by ceramic plate 23 which supports wafer 50. Susceptor plate 21 and ceramic plate 23 are supported by susceptor support arm 30 at susceptor hub receiver end 22. Susceptor support arm 30 is made of a ceramic material, preferably 99.5% alumina. A process gas flows through holes 11 formed in electrically biased gas distribution plate 12. Gas distribution plate 12 may be energized by the use of RF power which causes the process gas to form a plasma. Susceptor plate 21 is grounded by grounding conductor 32 which extends through an interior cavity of susceptor support arm 30. Thermocouple lead 33 is shown extending from a lower end of arm 50. During processing, susceptor disk 21 is heated by radiant heat from heating lamps 13 shining through a sealed quartz window 14. Susceptor temperatures may reach approximately 475 to 500 degrees Celsius.

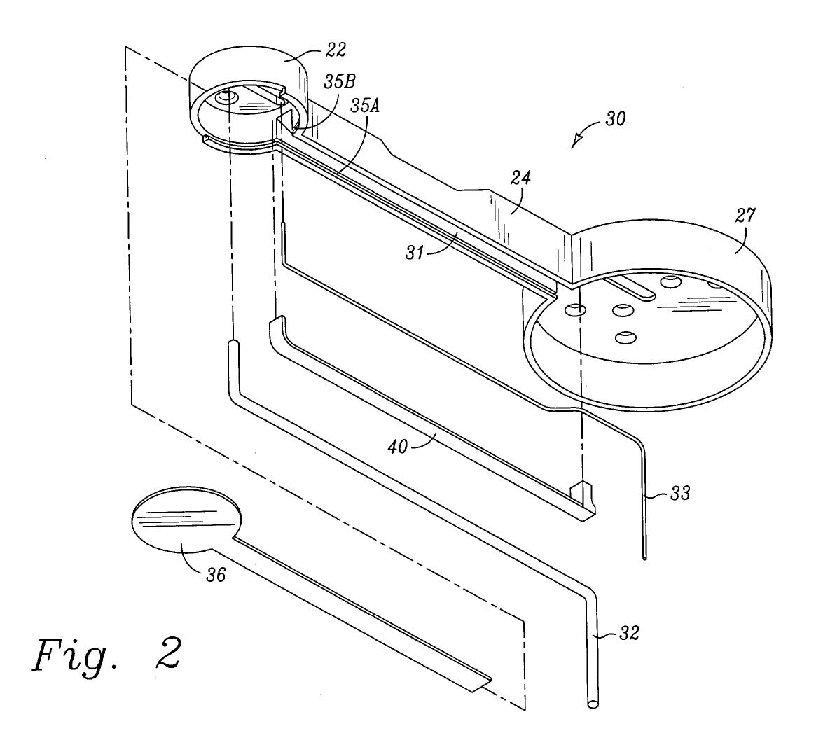

Referring to FIG. 2, susceptor support arm 30 includes channel 31 formed along a length of mid-section 24 to carry grounding conductor 32 which, in the preferred embodiment, is configured as a wire rope. Grounding conductor 32 passes through channel 31 formed on the interior of susceptor support arm 30 and terminates at first end 36 at ground receiving hole 37, shown in FIG. 4, formed in susceptor plate 21. A second end of grounding conductor 32 is secured to wall 15 of processing chamber 10 by connector 16, as shown in FIG. 1. Thermocouple lead 33 is also routed through channel 31 and terminates at first end 34 in a thermocouple receiving hole 35, shown in FIG. 4, formed in susceptor plate 21. Insulator strip 40 is disposed between grounding conductor 32 and thermocouple lead 33. Susceptor support arm 30 includes susceptor hub receiver end 22 and bellows end 27.

Grooves 35A and 35B formed in the sides of channel 31 slidably receive channel cover 36 to block radiation from the radiant heat lamps 13, shown in FIG. 1. Grooves 35A and 35B inside susceptor support arm channel 31 extend generally parallel to a throat of susceptor support arm 30 and around an inner perimeter of susceptor hub receiver end 22. Channel cover 36 is sized to fully cover susceptor support arm channel 31.

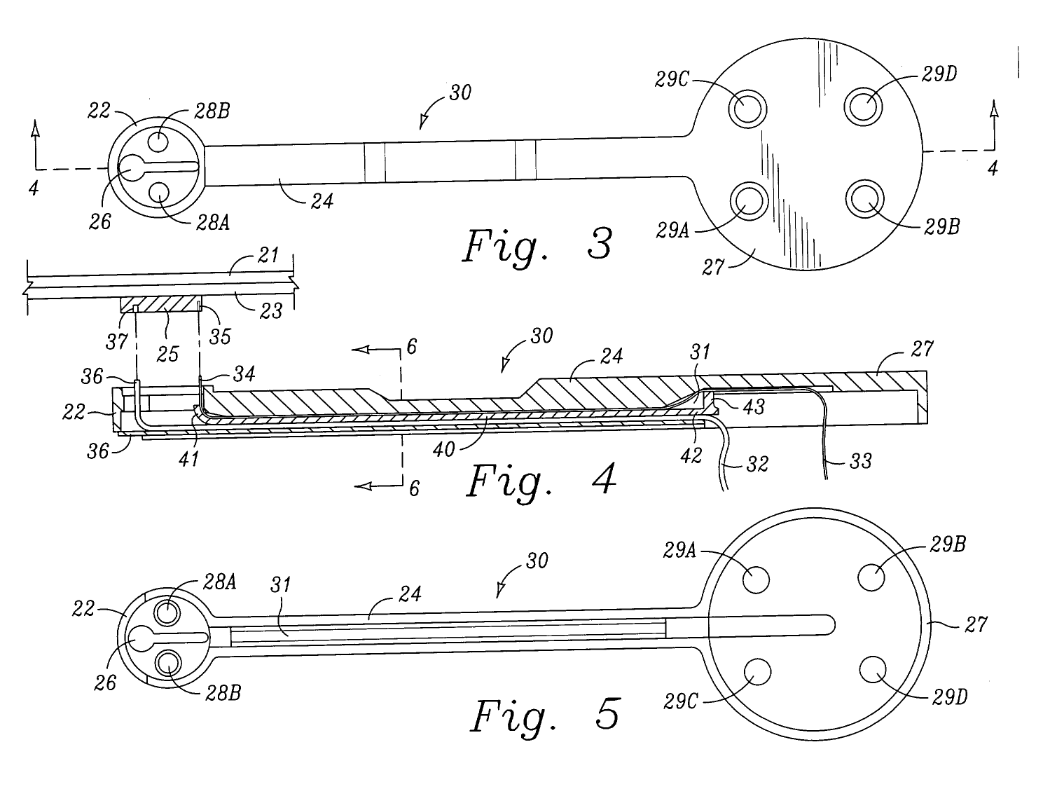

FIGS. 3, 4 and 5 are details showing susceptor support arm 30 including susceptor hub receiver end 22 and bellows end 27 connected by mid-section 24. As seen in FIGS. 3 and 5, keyhole shaped slot 26 is formed in susceptor hub receiver end 22 and permits for clearance and passage of grounding conductor 32 as seen in FIG. 4. Screw holes 28A and 28B are sized to receive fasteners to permit connection of susceptor plate 21 and ceramic plate 23 to susceptor support arm 30 at susceptor hub receiver end 22, as shown in FIG. 1. Bellows connecting holes 29A, 29B, 29C and 29D are sized to receive appropriately sized fasteners to permit connection of bellows end 27 which, as shown in FIG. 1, may be attached to an upper support end of arm 50.

Referring to FIGS. 4 and 5, susceptor support arm 30 includes channel 31 formed along a length and from an underside of mid-section 24. As seen in FIG. 4, insulator strip 40 is disposed between grounding conductor 32 and thermocouple lead 33. FIG. 4 shows susceptor plate 21 is backed by ceramic plate 23 positioned for connection to susceptor support arm 30 at susceptor hub receiver end 22. Grounding conductor 32 passes through channel 31, terminating at first end 36 which may be connected to at ground receiving hole 37 formed in susceptor plate 21 at susceptor hub 25. A second end of grounding conductor 32 is secured to wall 15 of processing chamber 10 by connector 16, as shown in FIG. 1. Thermocouple lead 33 is routed through channel 31 and terminates at first end 34 in thermocouple receiving hole 35, also formed in susceptor plate 21 at susceptor hub 25. Insulator strip 40 is disposed between grounding conductor 32 and thermocouple lead 33.

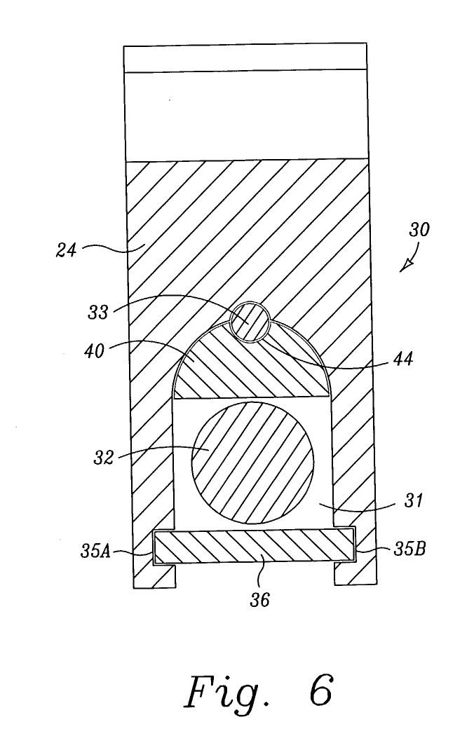

FIG. 6 is a representative cross-section of susceptor support arm 30 including channel 31. FIG. 6 shows the relative positioning of thermocouple lead 33, grounding conductor 32 and insulator strip 40. Channel cover 36 slideably engages grooves 35A and 35B formed on opposing inner walls of susceptor support arm channel 31.

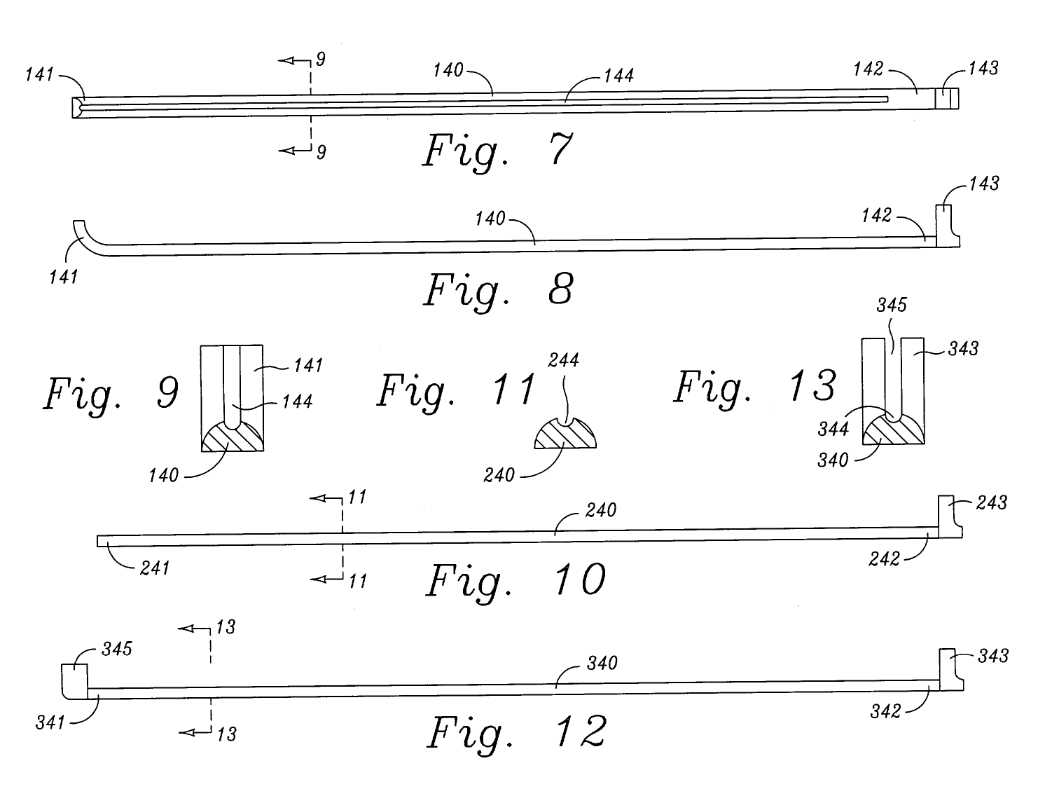

FIGS. 7 through 13 depict additional embodiments of the insulator strip of the present invention. FIGS. 7, 8 and 9 show insulator strip 140 including curved first end 141 and second end 142 including thermocouple lead retainer 143. Linear detent 144, shown in FIGS. 7 and 9, extends from first end 141 towards second end 142. As seen in FIG. 4, insulator strip 40 is disposed between grounding conductor 32 and thermocouple lead 33 passes along an upper surface of insulator strip 40 following generally the contour of the upper surface of insulator strip 40 from curved first end 41 to second end 42 and linear detent 144, shown in FIGS. 7 and 9, before passing on to thermocouple lead retainer 43, shown in FIG. 4.

FIGS. 10 and 11 show an alternate embodiment of insulator strip 240 including first end 241 and second end 242 including thermocouple lead retainer 243. Linear detent 244, shown in FIGS. 11, extends from first end 241 towards second end 242.

FIGS. 12 and 13 show an additional alternate embodiment of insulator strip 340 including first end 341 and second end 342 including thermocouple lead retainer 343. Linear detent 344, shown in FIG. 13, extends from first end 341 towards second end 342. Thermocouple guide 345 is formed at first end first end 341 for guiding and directing a thermocouple lead, (not shown in FIGS. 10 and 11), towards the susceptor plate.

While this invention has been described with reference to the detailed embodiments, this is not meant to be construed in a limiting sense. Various modifications to the described embodiments as well as the inclusion or exclusion of additional embodiments will be apparent to persons skilled in the art upon reference to this description. It is therefore contemplated that the appended claims will cover any such modifications or embodiments as fall within the true scope of the invention.

1. An insulator strip for a susceptor assembly including a support arm having a support arm channel, a ground strap and a thermocouple lead, the insulator strip comprising a strip of an insulating material configured for placement in the support arm channel between the ground strap and the thermocouple lead.

2. The insulator strip of claim 1 further comprising a strip of aluminum oxide material.

3. The insulator strip of claim 1 further comprising a strip of 99.5% aluminum oxide material.

4. The insulator strip of claim 1 further comprising a strip of an insulating material shaped to conform to a geometry of the support arm channel.

5. The insulator strip of claim 1 further comprising a bend formed a first end of the strip of insulating material locking member.

6. The insulator strip of claim 1 further comprising a locking member formed a first end of the strip of insulating material.

7. A susceptor assembly comprising:
a susceptor disk;
an insulating support disk attached to an underside of the susceptor disk;
a support arm attached to and supporting the susceptor disk and the insulating support disk, the susceptor support arm including a channel;
a ground wire conductively connected to the susceptor disk and extending along a length of the channel of the support arm;
a thermocouple lead connected to the susceptor disk and extending along a length of the channel of the support arm; and
an insulator strip extending along a length of the channel of the support arm, ii the insulator strip including a strip of an insulating material configured for placement in the channel of the support arm between the ground strap and the thermocouple lead.

8. The susceptor assembly of claim 7 further comprising a strip of aluminum oxide material.

9. The susceptor assembly of claim 7 further comprising a strip of 99.5% aluminum oxide material.

10. The susceptor assembly of claim 7 further comprising a strip of an insulating material shaped to conform to a geometry of the support arm channel.

11. The susceptor assembly of claim 7 further comprising a bend formed a first end of the strip of insulating material locking member.

12. The susceptor assembly of claim 7 further comprising a locking member formed a first end of the strip of insulating material.

13. The susceptor assembly of claim 7 further comprising a removable channel cover attached to the support arm to enclose a portion of the conductor in the channel.

14. The susceptor assembly of claim 13 wherein the channel cover is attached to the support arm within the channel by having opposed edges which slide into two slots facing one another on the inside of the channel.

15. A susceptor assembly for processing a substrate at temperatures of up to 500 degree Celsius comprising:
a susceptor having a substantially planar surface for supporting a substrate;
a ceramic susceptor support arm supporting the susceptor, the susceptor support arm including an open channel for routing wiring from a hub end of the support arm adjacent to the susceptor to a support end of the support arm distal from the susceptor, wherein the channel includes a removable channel cover attached to the support arm to enclose a portion of the conductor in the channel a susceptor disk;
an insulating support disk attached to an underside of the susceptor disk;
a ground wire conductively connected to the susceptor disk and extending along a length of the channel of the support arm;
a thermocouple lead connected to the susceptor disk and extending along a length of the channel of the support arm;
an insulator strip extending along a length of the channel of the support arm, the insulator strip including a strip of an insulating material configured for placement in the channel of the support arm between the ground strap and the thermocouple lead; and
a removable channel cover attached to the support arm to enclose a portion of the conductor and the insulator strip in the channel.

16. The susceptor assembly of claim 15 further comprising a strip of aluminum oxide material.

17. The susceptor assembly of claim 15 further comprising a strip of 99.5% aluminum oxide material.

18. The susceptor assembly of claim 15 further comprising a strip of an insulating material shaped to conform to a geometry of the support arm channel.

19. The susceptor assembly of claim 15 further comprising a bend formed a first end of the strip of insulating material locking member.

20. The susceptor assembly of claim 15 further comprising a locking member formed a first end of the strip of insulating material.
